(19) United States
(12) Patent Application Publication
(10) Pub. No.: US 2025/0038498 A1
(43) Pub. Date: Jan. 30, 2025

(54) ASSEMBLY

(71) Applicant: YOKOWO CO., LTD., Tokyo (JP)

(72) Inventors: Ryosuke FUJII, Gunma (JP); Kenji HAYAKAWA, Gunma (JP)

(73) Assignee: YOKOWO CO., LTD., Tokyo (JP)

(21) Appl. No.: 18/713,194

(22) PCT Filed: Nov. 21, 2022
(86) PCT No.: PCT/JP2022/042960

§ 371 Date: May 24, 2024

(30) Foreign Application Priority Data
Nov. 29, 2021 (JP) 2021-192804

(51) Int. Cl. H02G 3/08; H01Q 1/50; H05K 5/03

(52) U.S. Cl. CPC H02G 3/08; H05K 5/03; H01Q 1/50

(57) ABSTRACT

An assembly includes a first member; and a second member attached to the first member. A contact region where the first member and the second member are in contact with each other includes a first contact region. The first contact region is inclined with respect to a reference surface perpendicular to a direction in which the first member and the second member face each other.

TECHNICAL FIELD

The present invention relates to an assembly.

### BACKGROUND ART In the related art, as disclosed in Patent Literature 1, an assembly (electronic device)

to be attached to a vehicle, such as an antenna connection device, has been proposed.

### CITATION LIST

### Patent Literature

Patent Literature 1: JP2008-042373A

### SUMMARY OF INVENTION

### Technical Problem

However, for a member that constitutes the assembly, a variation due to a tolerance and deformation due to heat are not sufficiently considered, and it may be difficult to maintain an assembled state of the assembly.

Therefore, one example of an object of the present invention is to facilitate maintaining an assembled state of an assembly. Other objects of the present invention are apparent from description of the present specification.

### SOLUTION TO PROBLEM

An aspect of the present invention provides an assembly including a first member and a second member attached to the first member. A contact region where the first member and the second member are in contact with each other includes a first contact region. The first contact region is inclined with respect to a reference surface perpendicular to a direction in which the first member and the second member face each other.

According to the above aspect of the present invention, it is easy to maintain an assembled state of an assembly.

### BRIEF DESCRIPTION OF DRAWINGS

FIG. 1 is a perspective view of an in-vehicle device according to the present embodiment.

FIG. 2 is an exploded perspective view of the in-vehicle device before a cover and a holding portion are attached when viewed from above.

FIG. 3 is an exploded perspective view of the in-vehicle device before the cover and the holding portion are attached when viewed from below.

FIG. 4 is an enlarged exploded perspective view of a region where the cover, a substrate, and the holding portion in FIG. 2 are present.

FIG. 5 is an enlarged exploded perspective view of a region where the cover and the substrate in FIG. 3 are present.

FIG. 6 is a perspective view of the cover when viewed from below.

FIG. 7 is a cross-sectional view taken along a line B-B in FIG. 2, and is a yz-sectional view of a region where a first right inclined region of the cover is present.

FIG. 8 is an enlarged cross-sectional view of a region where a right claw portion in FIG. 7 is present.

FIG. 9 is a cross-sectional view taken along a line A-A in FIG. 1, and is a yz-sectional view of the cover, the substrate, and the holding portion when a thickness of at least one of the substrate and the holding portion is large.

FIG. 10 is a cross-sectional view taken along the line A-A in FIG. 1, and is a yz-sectional view of the cover, the substrate, and the holding portion when a thickness of at least one of the substrate and the holding portion is small.

### DESCRIPTION OF EMBODIMENTS

Hereinafter, the present embodiment will be described with reference to the drawings. The embodiment is not limited to the following embodiment. Further, contents described in one embodiment are similarly applied to other embodiments in principle. Further, the embodiments and modifications can be appropriately combined.

### Configuration of In-Vehicle Device 1

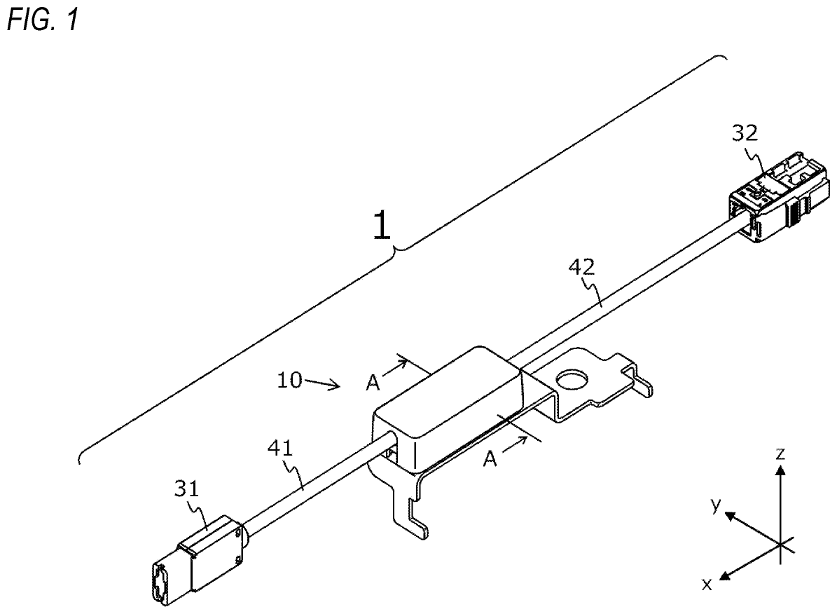

As shown in FIG. 1, an in-vehicle device 1 according to the present embodiment includes an electronic device (assembly) 10, a first connector 31, a second connector 32, a first cable 41, and a second cable 42. The electronic device 10 is used as a matching circuit of an antenna device (not shown). Details of the electronic device 10 will be described later. The first connector 31 is a connector for connecting to the antenna device. The second connector 32 is a connector for connecting to a signal processing device of the antenna device. For example, when the antenna device is an FM/AM receiving antenna device, the signal processing device is a radio tuner. The first cable 41 is used for electrical connection between the electronic device 10 and the first connector 31. The second cable 42 is used for electrical connection between the electronic device 10 and the second connector 32.

In order to describe directions, an x direction, a y direction, and a z direction are defined. The x direction is a longitudinal direction of a cover 11 of the electronic device 10, that is, a direction in which the first connector 31, the electronic device 10, and the second connector 32 are arranged in a state where the first cable 41 and the second cable 42 are extended straight. The y direction is one of horizontal directions perpendicular to the x direction. The z direction is one of vertical directions perpendicular to the x direction and the y direction. The z direction corresponds to a direction in which a first member and a second member face each other (a direction parallel to a perpendicular of a reference surface) in the claims. In the present embodiment, the x direction is described as a front-rear direction, the y direction as a left-right direction, and the z direction as an upper-lower direction. In FIG. 1 and the like, directions indicated by arrows of an x axis, a y axis, and a z axis are defined as a front direction, a right direction, and an upper direction, respectively. The front-rear direction of a vehicle to which the in-vehicle device 1 according to the present embodiment is attached may or may not coincide with the x direction.

### Electronic Device 10

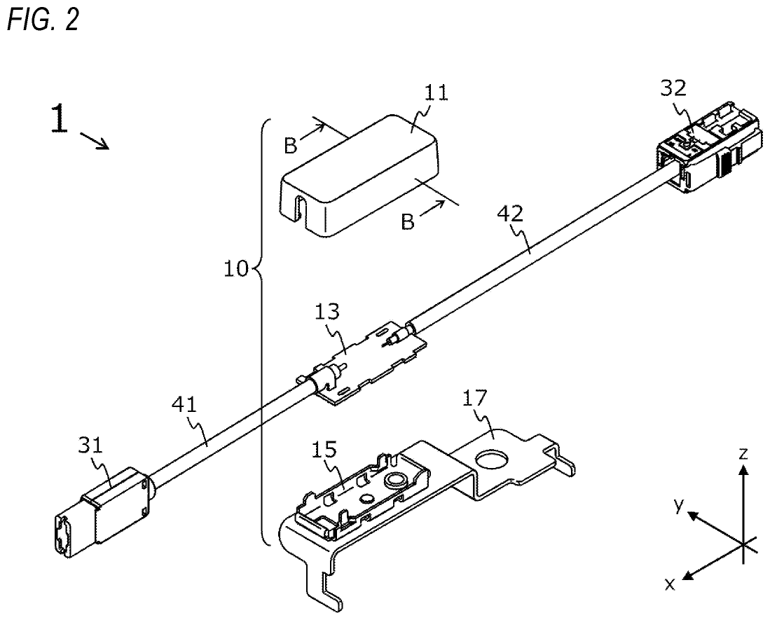

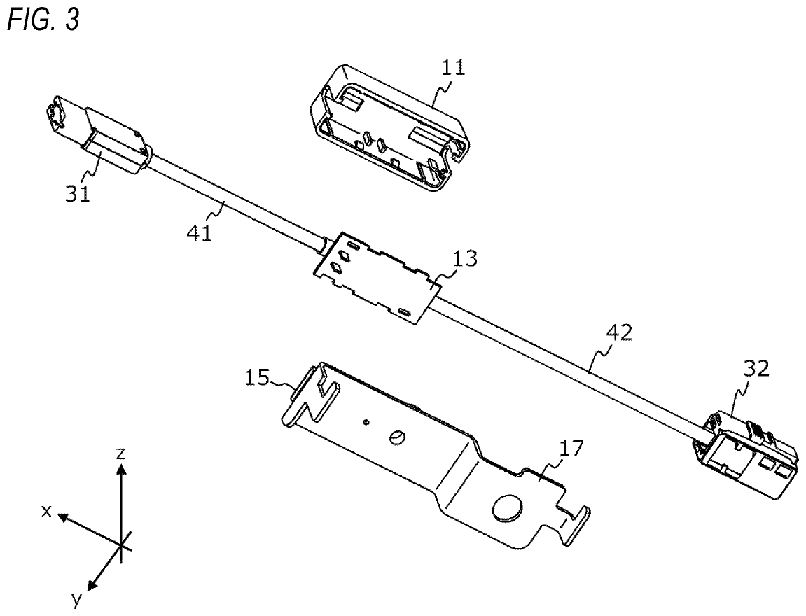

As shown in FIGS. 2 to 5, the electronic device 10 includes the cover (first member) 11, a substrate (sandwiched portion) 13, a holding portion (second member) 15, and a bracket 17. The cover 11 is hooked to the holding portion 15 in a state of sandwiching the substrate 13 in the z direction. An internal space is formed between the cover 11 and the holding portion 15, and the substrate 13 is fixed to the internal space. That is, the z direction is a direction in which the cover 11 and the holding portion 15 face each other, and is a direction in which the cover 11 and the holding portion 15 sandwich the substrate 13. The holding portion 15 to which the cover 11 and the substrate 13 are attached is attached to a vehicle (for example, inside a pillar) via the bracket 17.

### Cover 11

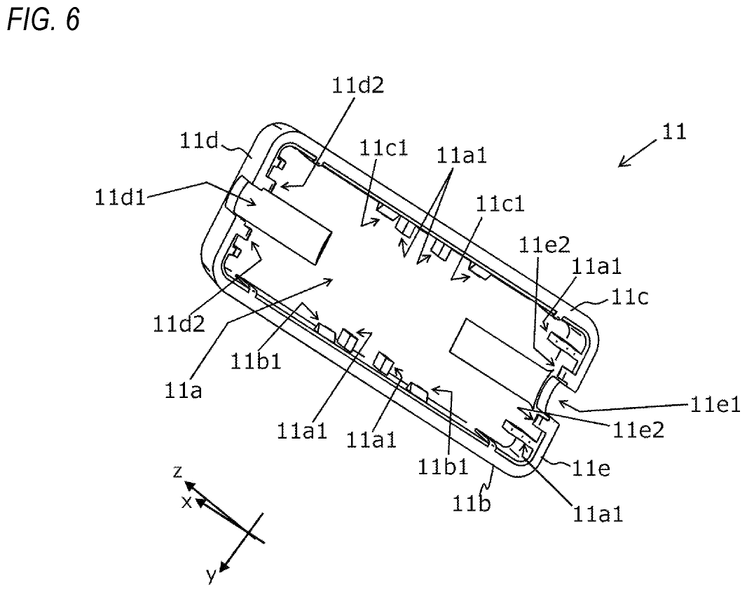

As shown in FIG. 6, the cover 11 has a substantially hollow rectangular parallelepiped shape with an open lower surface. The cover 11 is made of resin. The cover 11 includes an upper surface portion 11a, a right side surface portion 11b, a left side surface portion 11c, a front surface portion 11d, and a rear surface portion 11e. The upper surface portion 11a, the right side surface portion 11b, the left side surface portion 11c, the front surface portion 11d,and the rear surface portion 11e are integrally implemented.

### Upper Surface Portion 11a

The upper surface portion 11a has a surface substantially perpendicular to the z direction, and constitutes an upper surface of the cover 11. The right side surface portion 11b extends downward in the z direction from a right end portion of the upper surface portion 11a. The left side surface portion 11c extends downward in the z direction from a left end portion of the upper surface portion 11a. The front surface portion 11d extends downward in the z direction from a front end portion of the upper surface portion 11a. The rear surface portion 11e extends downward in the z direction from a rear end portion of the upper surface portion 11a. Ribs 11a1 that protrude downward in the z direction are provided on a lower surface of the upper surface portion 11a. The rib 11a1 is different from a hooking portion of the first member in the claims.

The ribs 11a1 press a substrate main body 13a from above in the z direction. The rib 11a1 may be provided on an inner wall of a side surface portion (the right side surface portion 11b, the front surface portion 11d, or the like). For example, the rib 11a1 according to the present embodiment is in contact with an inner wall of any one of the right side surface portion 11b, the left side surface portion 11c, the front surface portion 11d, and the rear surface portion 11e and the lower surface of the upper surface portion 11a.

### Right Side Surface Portion 11b

The right side surface portion 11b has a surface substantially perpendicular to the y direction, and constitutes a right surface of the cover 11. Right claw portions 11b1 that protrude leftward in the y direction are provided on a lower portion of an inner side surface of the right side surface portion 11b. The right claw portion 11b1 comes into contact with a region of a right wall 15b to be described later in contact with an upper edge of a right hooking hole 15b1. The right claw portions 11b1 constitute a right hooking portion of the cover 11.

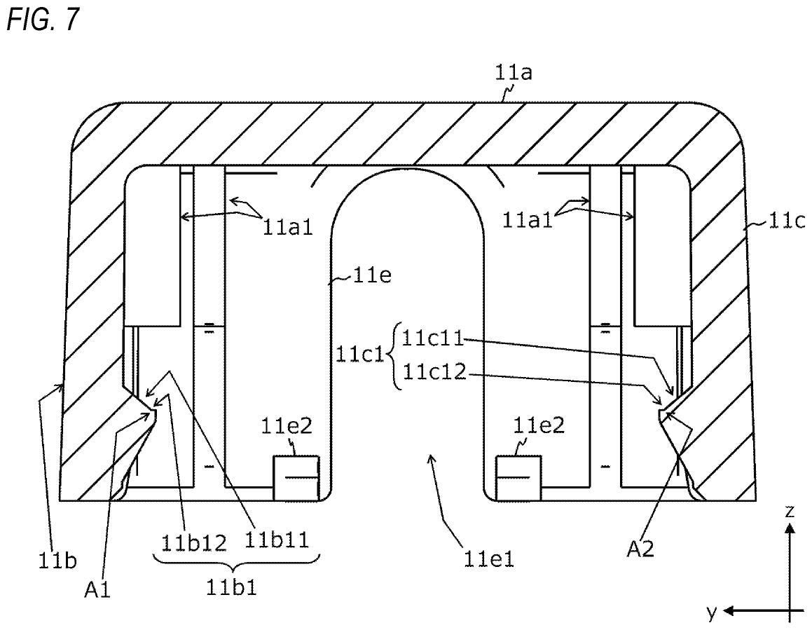

As shown in FIG. 7, a region of the right claw portion 11b1 in contact with the right wall 15b includes a first right contact region 11b11 and a second right contact region 11b12. The first right contact region 11b11 forms an inclined surface that extends obliquely leftward and downward from the inner side surface of the right side surface portion 11b. The second right contact region 11b12 is adjacent to the first right contact region 11b11, and is located closer to a tip end of the right claw portion 11b1 than the first right contact region 11b11. The second right contact region 11b12 forms a flat surface that extends leftward in the y direction from the lower end portion of the first right contact region 11b11, or an inclined surface that extends obliquely leftward and downward from the lower end portion of the first right contact region 11b11.

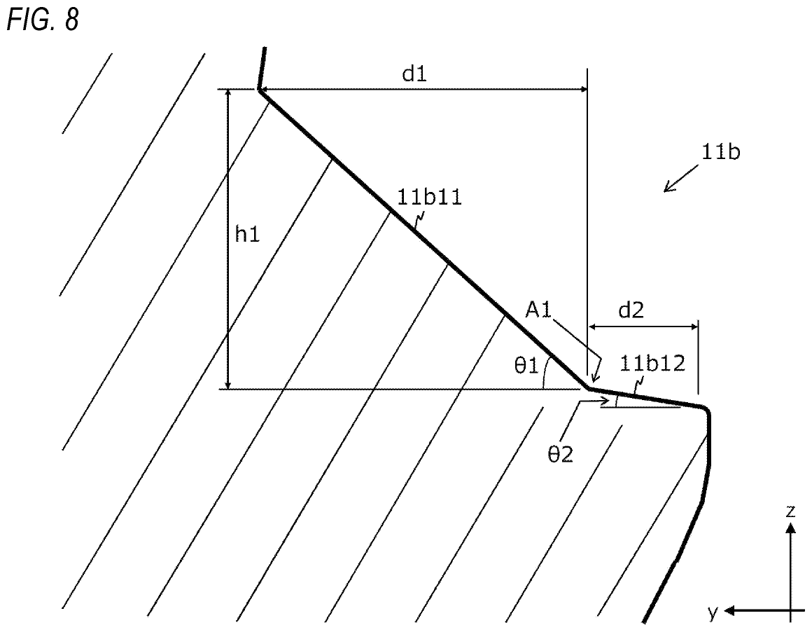

That is, the first right contact region 11b11 is inclined with respect to a xy plane (reference surface). Further, the second right contact region 11b12 is parallel to the xy plane, or is inclined at an angle different from that of the first right contact region 11b11 with respect to the xy plane. Specifically, as shown in FIG. 8, an inclination angle (first inclination angle 01) of an inclined surface that forms the first right contact region 11b11 with respect to the xy plane is larger than an inclination angle (second inclination angle θ2) of a flat surface or an inclined surface that forms the second right contact region 11b12 with respect to the xy plane (90°>θ1>θ2>0°). A valley portion (first valley portion A1) is formed on a boundary portion between the first right contact region 11b11 and the second right contact region 11b12 on a side facing the right wall 15b.

By providing the first right contact region 11b11 having an inclination (90°>θ1>0°), it is possible to absorb a thickness variation or the like of the sandwiched portion (substrate 13) and to perform assembly without generating rattling. By providing the second right contact region 11b12 having an inclination gentler than that of the first right contact region 11b11 (θ1>θ2>0°), even if the right claw portion 11b1 in contact with the right hooking hole 15b1 in the first right contact region 11b11 is displaced and a contact position is changed, the first valley portion A1 or the second right contact region 11b12 is caught by the right hooking hole 15b1. That is, the right claw portion 11b1 is less likely to be detached from the right wall 15b, and the cover 11 is less likely to be removed from the holding portion 15.

A width of the first right contact region 11b11, that is, a width of the inclined surface that forms the first right contact region 11b11 (a dimension in the y direction, a first width d1) is larger than a width of the second right contact region 11b12, that is, a width of the flat surface or the inclined surface that forms the second right contact region 11b12 (a dimension in the y direction, a second width d2) (d1>d2). When the first width d1 is increased, a region in contact with the right hooking hole 15b1 of the first right contact region 11b11 can be increased, and it is easy to absorb the thickness variation or the like of the sandwiched portion (substrate 13). In order to make the right claw portion 11b1 less likely to be detached from the right wall 15b by catching, the second width d2 (a protruding amount of the second right contact region 11b12 in the y direction) is adjusted based on a holding force of the cover 11 and the holding portion 15, or the like.

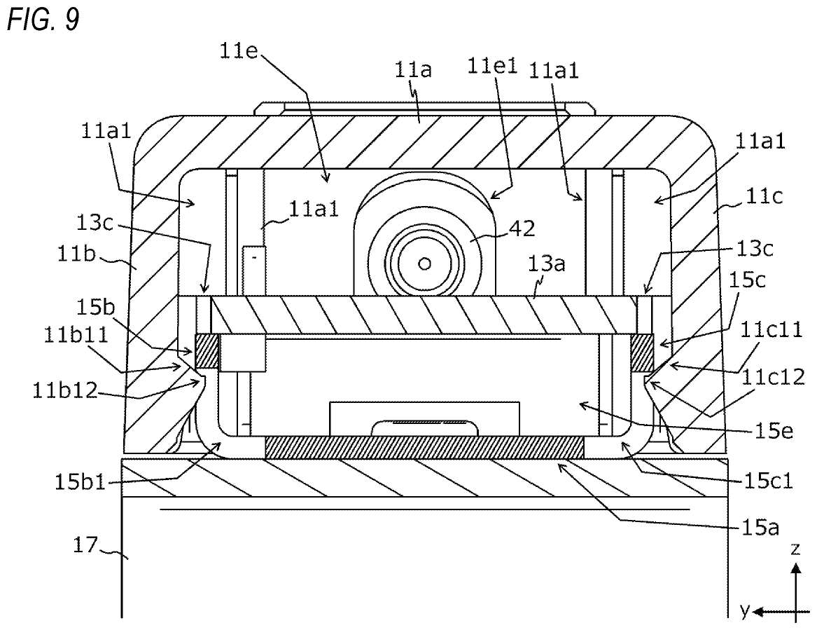

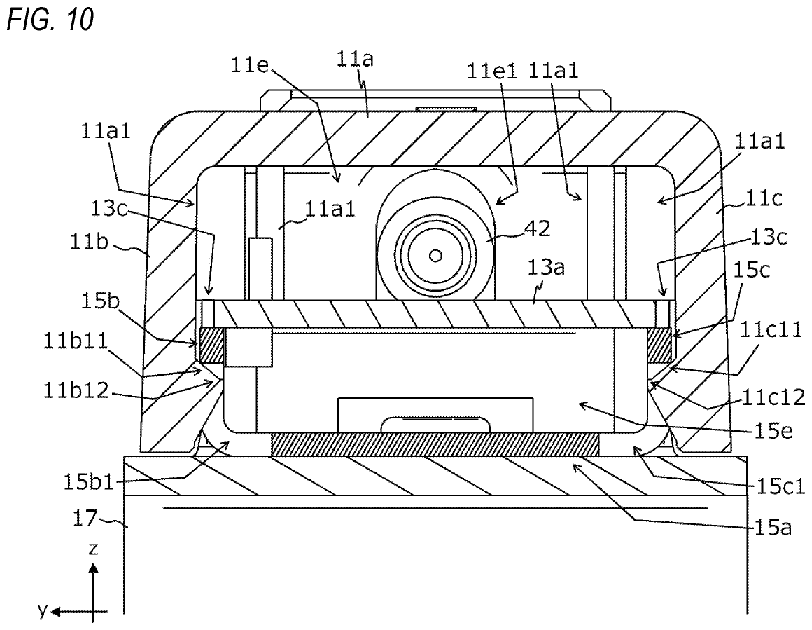

A height of the inclined surface that forms the first right contact region 11b11 (a dimension in the z direction, a slope height h1) is determined so as to satisfy the following conditions. Due to a tolerance, thermal expansion, thermal contraction, and the like, when a thickness of at least one of the substrate 13 and the holding portion 15 is large (see FIG. 9), a lower end of the first right contact region 11b11 is in contact with the right wall 15b, and when the thickness of at least one of the substrate 13 and the holding portion 15 is small (see FIG. 10), an upper end of the first right contact region 11b11 is in contact with the right wall 15b.

### Left Side Surface Portion 11c

The left side surface portion 11c has a surface substantially perpendicular to the y direction, and constitutes a left surface of the cover 11. Left claw portions 11c1 that protrude rightward in the y direction are provided on a lower portion of an inner side surface of the left side surface portion 11c. The left claw portion 11c1 comes into contact with a region of a left wall 15c to be described later in contact with an upper edge of a left hooking hole 15c1. The left claw portions 11c1 constitute a left hooking portion of the cover 11.

A region in contact with the left wall 15c of the left claw portion 11c1 includes a first left contact region 11c11 and a second left contact region 11c12 (see FIG. 7). The first left contact region 11c11 forms an inclined surface that extends obliquely rightward and downward from the inner side surface of the left side surface portion 11c. The second left contact region 11c12 is adjacent to the first left contact region 11c11, and is located closer to a tip end of the left claw portion 11c1 than the first left contact region 11c11. The second left contact region 11c12 forms a flat surface that extends rightward in the y direction from a lower end portion of the first left contact region 11c11, or an inclined surface that extends obliquely rightward and downward from the lower end portion of the first left contact region 11c11.

That is, the first left contact region 11c11 is inclined with respect to the xy plane (reference surface). Further, the second left contact region 11c12 is parallel to the xy plane, or is inclined at an angle different from that of the first left contact region 11c11 with respect to the xy plane. An inclination angle of the inclined surface that forms the first left contact region 11c11 with respect to the xy plane is larger than an inclination angle of the flat surface or the inclined surface that forms the second left contact region 11c12 with respect to the xy plane. A valley portion (second valley portion A2) is formed on a boundary portion between the first left contact region 11c11 and the second left contact region 11c12 on a side facing the left wall 15c.

By providing the first left contact region 11c11 having inclination, it is possible to absorb the thickness variation or the like of the sandwiched portion (substrate 13), and to perform assembly without generating rattling. By providing the second left contact region 11c12 having an inclination gentler than that of the first left contact region 11c11, even if the left claw portion 11c1 in contact with the left hooking hole 15c1 in the first left contact region 11c11 is displaced and a contact position is changed, the second valley portion A2 or the second left contact region 11c12 is caught by the left hooking hole 15c1. That is, the left claw portion 11c1 is less likely to be detached from the left wall 15c, and the cover 11 is less likely to be removed from the holding portion 15.

A width of the first left contact region 11c11, that is, a width of the inclined surface that forms the first left contact region 11c11 (a dimension in the y direction) is larger than a width of the second left contact region 11c12, that is, a width of the flat surface or the inclined surface that forms the second left contact region 11c12 (a dimension in the y direction). When the width of the first left contact region 11c11 is increased, a region in contact with the left hooking hole 15c1 of the first left contact region 11c11 can be increased, and it is easy to absorb the thickness variation or the like of the sandwiched portion (substrate 13). In order to make the left claw portion 11c1 less likely to be detached from the left wall 15c by catching, the width of the second left contact region 11c12 (a protruding amount of the second right contact region 11b12) is adjusted based on the holding force of the cover 11 and the holding portion 15, or the like.

A height (a dimension in the z direction) of the inclined surface that forms the first left contact region 11c11 is determined so as to satisfy the following conditions. Due to a tolerance, thermal expansion, thermal contraction, and the like, when the thickness of at least one of the substrate 13 and the holding portion 15 is large, a lower end of the first left contact region 11c11 is in contact with the left wall 15c, and when the thickness of at least one of the substrate 13 and the holding portion 15 is small, an upper end of the first left contact region 11c11 is in contact with the left wall 15c.

### Symmetry of Right Claw Portion 11b1 and Left Claw Portion 11c1

A region in contact with the right wall 15b of the right claw portion 11b1 and a region in contact with the left wall 15c of the left claw portion 11c1 are bilaterally symmetrical when viewed from the x direction. That is, the first right contact region 11b11 and the first left contact region 11c11 are disposed to be bilaterally symmetrical with the same dimensions, and the second right contact region 11b12 and the second left contact region 11c12 are disposed to be bilaterally symmetrical with the same dimensions.

### Front Surface Portion 11d

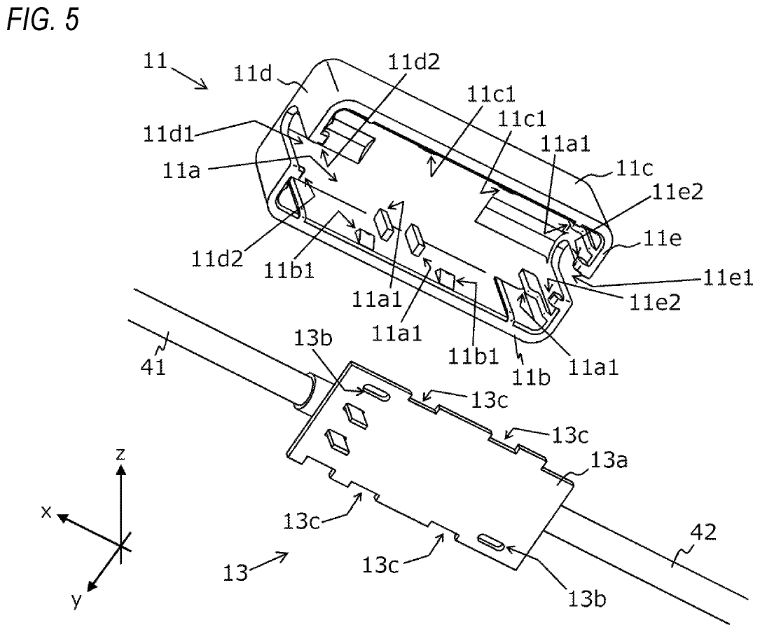

The front surface portion 11d has a surface substantially perpendicular to the x direction, and constitutes a front surface of the cover 11 (see FIGS. 5 and 6). In a lower end portion of a center in the y direction of the front surface portion 11d, a cutout (front cut-out portion 11d1) is provided upward in the z direction from the lower end portion. The front cut-out portion 11d1 has a substantially U shape when viewed from the x direction. When the cover 11 is attached to the holding portion 15 in a state where the substrate 13 is attached, the first cable 41 passes through the front cut-out portion 11d1. Front claw portions 11d2 that protrude rearward in the x direction are provided on a lower end portion of an inner side surface of the front surface portion 11d. When the cover 11 is attached to the holding portion 15 in a state where the substrate 13 is attached, the front claw portion 11d2 is engaged with a front hooking convex portion 15d1 to be described later.

### Rear Surface Portion 11e

The rear surface portion 11e has a surface substantially perpendicular to the x direction, and constitutes a rear surface of the cover 11. In a lower end portion of a center in the y direction of the rear surface portion 11e, a cutout (rear cut-out portion 11e1) is provided upward in the z direction from the lower end portion. The rear cut-out portion 11e1 has a substantially U shape when viewed from the x direction. When the cover 11 is attached to the holding portion 15 in a state where the substrate 13 is attached, the second cable 42 passes through the rear cut-out portion 11e1. Rear claw portions 11e2 that protrude forward in the x direction are provided on a lower end portion of an inner side surface of the rear surface portion 11e. When the cover 11 is attached to the holding portion 15 in a state where the substrate 13 is attached, the rear claw portion 11e2 is engaged with a rear hooking convex portion 15e1 to be described later.

### Substrate 13

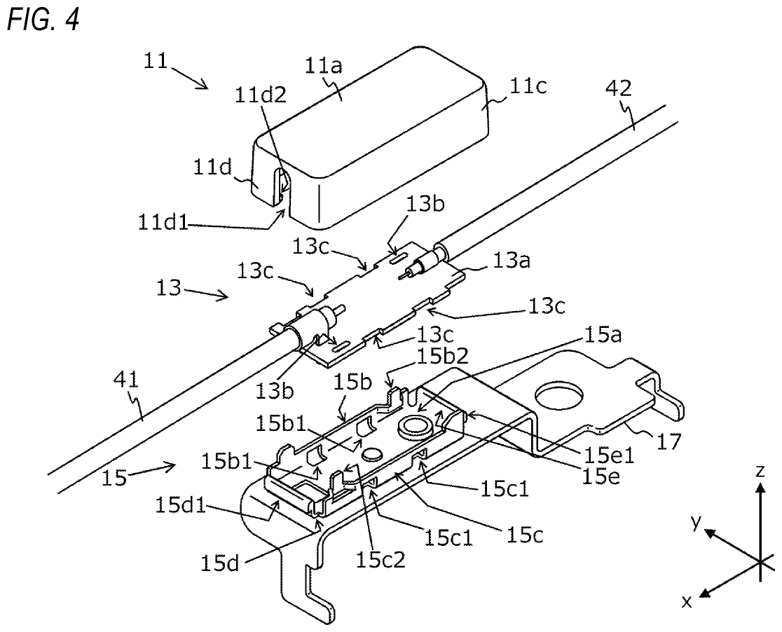

The substrate main body 13a of the substrate 13 includes a circuit that performs impedance matching or the like related to a reception signal or a transmission signal of an antenna device connected via the first connector 31, such as a matching circuit (see FIG. 4). The substrate 13 is connected to the first cable 41 on a front side in the x direction, and is connected to the second cable 42 on a rear side in the x direction. The substrate main body 13a is formed with solder connection holes 13b and claw cutouts 13c. When attaching the substrate 13 to the holding portion 15, a right solder connection convex portion 15b2 and a left solder connection convex portion 15c2 of the holding portion 15 are fitted into and soldered to the solder connection holes 13b. The claw cutout 13c is provided in an end portion of the substrate main body 13a in the y direction.

When the cover 11 is attached to the holding portion 15 in a state where the substrate 13 is attached, the right claw portion 11b1 of the cover 11 passes through the claw cutout 13c on a right side in the y direction, and the left claw portion 11c1 of the cover 11 passes through the claw cutout 13c on a left side in the y direction. By providing the claw cutout 13c, it is possible to prevent the right claw portion 11b1 and the left claw portion 11c1 from hitting the substrate main body 13a and damaging the substrate main body 13a.

### Holding Portion 15

The holding portion 15 holds the substrate 13. The substrate 13 and the holding portion 15 are attached by fitting, soldering, or the like. The cover 11 is hooked to the holding portion 15 in a detachable state. Specifically, the cover 11 is attached to the holding portion 15 by hooking the right claw portion 11b1 on the right hooking hole 15b1, hooking the left claw portion 11c1 on the left hooking hole 15c1, hooking the front claw portion 11d2 on the front hooking convex portion 15d1, and hooking the rear claw portion 11e2 on the rear hooking convex portion 15e1.

The holding portion 15 has a substantially hollow rectangular parallelepiped shape with an open upper surface. The holding portion 15 includes a holding portion main body 15a, the right wall 15b, the left wall 15c, a front wall 15d, and a rear wall 15e. The holding portion main body 15a, the right wall 15b, the left wall 15c, the front wall 15d, and the rear wall 15e are integrally implemented. The holding portion 15 is made of metal, and is electrically connected to the substrate 13 and the bracket 17.

### Holding Portion Main Body 15a

The holding portion main body 15a has a surface substantially perpendicular to the z direction, and constitutes a lower surface of the holding portion 15. The holding portion main body 15a is fixed to the bracket 17 by screwing, fitting, welding, or the like. The right wall 15b extends upward in the z direction from a right end portion of the holding portion main body 15a. The left wall 15c extends upward in the z direction from a left end portion of the holding portion main body 15a. The front wall 15d extends upward in the z direction from a front end portion of the holding portion main body 15a. The rear wall 15e extends upward in the z direction from a rear end portion of the holding portion main body 15a.

### Right Wall 15b

The right wall 15b has a surface substantially perpendicular to the y direction, and constitutes a right surface of the holding portion 15. The right wall 15b is formed with a hole for hooking the right claw portion 11b1 (right hooking hole 15b1). The right wall 15b and the right hooking holes 15b1 constitute a right hooked portion of the holding portion 15. Further, a protrusion (right solder connection convex portion 15b2) that protrudes upward in the z direction is provided on an upper portion of the right wall 15b.

### Left Wall 15c

The left wall 15c has a surface substantially perpendicular to the y direction, and constitutes a left surface of the holding portion 15. The left wall 15c is formed with a hole for hooking the left claw portion 11c1 (left hooking hole 15c1). The left wall 15c and the left hooking holes 15c1 constitute a left hooked portion of the holding portion 15. Further, a protrusion (left solder connection convex portion 15c2) that protrudes upward in the z direction is provided on an upper portion of the left wall 15c.

### Front Wall 15d

The front wall 15d has a surface substantially perpendicular to the x direction, and constitutes a front surface of the holding portion 15. The front hooking convex portion 15d1 that protrudes forward in the x direction is provided on an upper portion of the front wall 15d.

### Rear Wall 15e

The rear wall 15e has a surface substantially perpendicular to the x direction, and constitutes a rear surface of the holding portion 15. The rear hooking convex portion 15e1 that protrudes rearward in the x direction is provided on an upper portion of the rear wall 15e.

### Bracket 17

The bracket 17 is made of metal. The bracket 17 is attached to a metal portion of the vehicle. Grounding is performed by attaching the substrate 13 to the holding portion 15, attaching the holding portion 15 to the bracket 17, and attaching the bracket 17 to the metal portion of the vehicle. The holding portion 15 and the bracket 17 are attached by screwing, fitting, welding, or the like. Further, the holding portion 15 and the bracket 17 may be integrally implemented.

Assembly Procedure

Next, an assembly procedure of the electronic device 10 will be described. The first cable 41 is previously attached to a front side of the substrate main body 13a in the x direction by soldering. Further, the second cable 42 is attached to a rear side of the substrate main body 13a in the x direction by soldering.

The holding portion 15 is attached to the bracket 17 (holding portion attaching step). The substrate 13 is attached to the holding portion 15 (substrate attaching step). Specifically, the right solder connection convex portion 15b2 and the left solder connection convex portion 15c2 of the holding portion 15 are fitted into the solder connection holes 13b of the substrate main body 13a, and then fixed by soldering.

The cover 11 is attached to the holding portion 15 (cover attaching step). Specifically, the right claw portion 11b1 is hooked to the right hooking hole 15b1, and the left claw portion 11c1 is hooked to the left hooking hole 15c1 (see FIGS. 9 and 10). Further, the front claw portion 11d2 is hooked to the front hooking convex portion 15d1, and the rear claw portion 11e2 is hooked to the rear hooking convex portion 15e1.

At this time, the ribs 11a1 of the cover 11 come into contact with an upper surface of the substrate main body 13a, and apply a downward force in the z direction to the substrate main body 13a. Further, the right claw portion 11b1 comes into contact with the right wall 15b, and applies an upward force in the z direction to the substrate main body 13a via the right wall 15b. Specifically, the region of the right wall 15b in contact with the upper edge of the right hooking hole 15b1 comes into contact with the first right contact region 11b11 of the right claw portion 11b1. Further, the left claw portion 11c1 comes into contact with the left wall 15c, and applies an upward force in the z direction to the substrate main body 13a via the left wall 15c. Specifically, the region of the left wall 15c in contact with the upper edge of the left hooking hole 15c1 comes into contact with the first left contact region 11c11 of the left claw portion 11c1.

Accordingly, the cover 11 is fixed to the holding portion 15 in a state where the substrate 13 is sandwiched in the z direction. Further, a state where the cover 11 is hooked to the holding portion 15 is maintained in a state where a contact position between the cover 11 and the holding portion 15 can be changed by the inclined surface of the first right contact region 11b11 and the inclined surface of the first left contact region 11c11.

As shown in FIG. 9, when at least one of the substrate 13 in which a thickness of the substrate main body 13a in the z direction is larger than that of the average substrate main body 13a and the holding portion 15 in which a thickness in the z direction is larger than that of the average holding portion 15 is used due to a tolerance, a lower portion of the first right contact region 11b11 in the z direction comes into contact with the right wall 15b, and a lower portion of the first left contact region 11c11 in the z direction comes into contact with the left wall 15c. In at least one of a case where the thickness of the substrate main body 13a in the z direction is increased and a case where the thickness of the holding portion 15 in the z direction is increased due to thermal expansion, the lower portion of the first right contact region 11b11 in the z direction comes into contact with the right wall 15b, and the lower portion of the first left contact region 11c11 in the z direction comes into contact with the left wall 15c.

As shown in FIG. 10, when at least one of the substrate 13 in which the thickness of the substrate main body 13a in the z direction is smaller than that of the average substrate main body 13a and the holding portion 15 in which the thickness in the z direction is smaller than that of the average holding portion 15 is used due to a tolerance, an upper portion of the first right contact region 11b11 in the z direction comes into contact with the right wall 15b, and an upper portion of the first left contact region 11c11 in the z direction comes into contact with the left wall 15c. In at least one of a case where the thickness of the substrate main body 13a in the z direction is reduced and a case where the thickness of the holding portion 15 in the z direction is reduced due to thermal contraction, the upper portion of the first right contact region 11b11 in the z direction comes into contact with the right wall 15b, and the upper portion of the first left contact region 11c11 in the z direction comes into contact with the left wall 15c.

### Effects of Forming Contact Region by Inclined Surface

During hooking, a region of the hooking portion (right claw portion 11b1, left claw portion 11c1) in contact with the hooked portion (right wall 15b, left wall 15c) can be displaced along an inclined surface. Therefore, even if a variation in a size occurs due to a tolerance, thermal expansion, thermal contraction, or the like, rattling cannot be generated, and fixation by hooking can be maintained. That is, an assembled state of an assembly such as the electronic device 10 is easily maintained.

The cover 11 can be attached to the holding portion 15 without using a screw. Therefore, the electronic device 10 can be miniaturized, and the electronic device 10 can be implemented at low cost. Further, since a screw made of metal is not used, as compared with a configuration in which the screw made of metal is used, effects of preventing noise from being generated are also obtained.

### Effects of Providing Second Right Contact Region 11b12 and Second Left Contact Region 11c12

The second right contact region 11b12 having a different inclination angle is provided on the tip end of the first right contact region 11b11, and the valley portion (first valley portion A1) is formed on the boundary portion between the first right contact region 11b11 and the second right contact region 11b12 when viewed from the x direction. The second left contact region 11c12 having a different inclination angle is provided on the tip end of the first left contact region 11c11, and the valley portion (second valley portion A2) is formed on the boundary portion between the first left contact region 11c11 and the second left contact region 11c12 when viewed from the x direction.

Even if the contact portion with the right wall 15b is displaced downward in the z direction of the first right contact region 11b11, the contact portion with the right wall 15b is less likely to be displaced to the second right contact region 11b12 beyond the first valley portion A1, and the right claw portion 11b1 is less likely to be detached from the right hooking hole 15b1. Even if the contact portion with the left wall 15c is displaced downward in the z direction of the first left contact region 11c11, the contact portion with the left wall 15c is less likely to be displaced to the second left contact region 11c12 beyond the second valley portion A2, and the left claw portion 11c1 is less likely to be detached from the left hooking hole 15c1. That is, as compared with a configuration in which the second right contact region 11b12 and the second left contact region 11c12 are not provided, a state where the cover 11 is hooked to the holding portion 15 is easily maintained.

### Effects of Inserting Substrate 13 in Z Direction

The sandwiched portion (substrate 13) is inserted between the cover 11 and the holding portion 15, so that it is easy to maintain the state where the cover 11 is hooked to the holding portion 15 without generating rattling.

### Effects of Forming Cover 11 with Resin

As compared with a configuration in which the cover 11 is made of metal, the cover 11 can be lightweight and inexpensive. Even if the cover 11 is made of resin, according to the present embodiment, the contact position between the hooking portion and the hooked portion can be adjusted by an inclined surface of a contact region (first right contact region 11b11 or the like) of a claw portion. Therefore, an attachment state (hooked state) of the assembly (electronic device 10) can be easily maintained without generating rattling.

### Application Example of Cover 11

In the present embodiment, an example in which the cover 11 is made of resin has been described. However, the cover 11 may be made of metal.

### Application Example of Assembly Other Than Electronic Device 10

In the present embodiment, an example has been described in which the cover 11 corresponding to the first member is hooked to the holding portion 15 corresponding to the second member to form the electronic device 10 corresponding to the assembly. However, the assembly is not limited to the electronic device 10 including the substrate 13, and may be another assembly (for example, a container) including the first member that includes the hooking portion and the second member that includes the hooked portion.

### Application Example 1 of Sandwiched Portion (Substrate 13)

In the present embodiment, an example has been described in which the substrate 13 corresponding to the sandwiched portion includes the matching circuit. However, the substrate 13 may include another circuit such as an amplifier circuit without including the matching circuit.

### Application Example 2 of Sandwiched Portion (Substrate 13)

In the present embodiment, an example has been described in which the substrate 13 corresponding to the sandwiched portion is configured separately from the cover 11 corresponding to the first member and the holding portion corresponding to the second member. However, the sandwiched portion may be implemented integrally with the first member, or may be implemented integrally with the second member.

### Application Example 1 of Hooking Portion and Hooked Portion

In the present embodiment, an example has been described in which the hooking portion of the cover (first member) 11 includes the claw portions (the right claw portion 11b1 and the left claw portion 11c1), and the hooked portion of the holding portion (second member) 15 includes the hooking holes (the right hooking hole 15b1 and the left hooking hole 15c1). However, the hooking portion and the hooked portion are not limited to a combination of the claw and the hole. For example, the hooking portion and the hooked portion may be implemented by a claw and another claw to be engaged with the claw.

### Application Example 2 of Hooking Portion and Hooked Portion

In the present embodiment, an example has been described in which the cover 11 corresponds to the first member and includes the hooking portion, and the holding portion 15 corresponds to the second member and includes the hooked portion. However, the cover 11 may correspond to the second member and include the hooked portion, and the holding portion 15 may correspond to the first member and include the hooking portion. In this case, the cover 11 is provided with a hole or a cutout corresponding to the hooking hole, and the holding portion 15 is provided with a protrusion corresponding to the claw portion. Further, both the cover 11 and the holding portion 15 may correspond to the first member and include the hooking portion, and both the cover 11 and the holding portion 15 may correspond to the second member and include the hooked portion.

### Application Example 3 of Hooking Portion and Hooked Portion

In the present embodiment, an example has been described in which the hooking holes (the right hooking hole 15b1 and the left hooking hole 15c1) are formed in the right wall 15b and the left wall 15c, and the upper edges of the holes and the boundary portions of the walls come into contact with the claw portions (the right claw portion 11b1 and the left claw portion 11c1). However, a region to be hooked is not limited to a hole, and may have another shape such as a cutout or a flange.

### Application Example 4 of Hooking Portion and Hooked Portion

In the present embodiment, an example has been described in which the inclined regions (the first right contact region 11b11 and the like) are provided on the hooking portions (the right claw portion 11b1 and the left claw portion 11c1) provided on the tip end portion of the cover 11. However, the inclined region may be provided on the member (rib 11a1) that sandwiches the sandwiched portion (substrate 13) with the hooking portion. In this case, an inclined surface is formed in a region in contact with a contacted portion of the member. In a state where a contact position between the contacted portion and the member can be changed, a state where the hooking portion is hooked to the hooked portion is maintained. The member is not limited to the reinforcing rib 11a1 in the cover 11, and may be implemented by a protrusion or the like different from the rib 11a1.

While certain embodiments of the present invention are described, these embodiments are presented by way of examples only, and are not intended to limit the scope of the present invention. These embodiments can be implemented by various other forms, and various omissions, replacements, and modifications can be made without departing from the gist of the invention. These embodiments and modifications thereof are included in the scope and the gist of the invention, and are included in a scope equivalent to the inventions described in the claims.

### According to the present specification, the following aspects are provided.

### Aspect 1

An assembly includes a first member and a second member attached to the first member. A contact region where the first member and the second member are in contact with each other includes a first contact region. The first contact region is inclined with respect to a reference surface perpendicular to a direction in which the first member and the second member face each other.

According to Aspect 1, even if a variation in size occurs due to a tolerance, thermal expansion, thermal contraction, or the like, it is easy to maintain an assembled state of the assembly without generating rattling.

### Aspect 2

Preferably, the contact region includes the first contact region and a second contact region. The second contact region is adjacent to the first contact region, and is located closer to a tip end than the first contact region. The second contact region is parallel to the reference surface, or is inclined at an angle different from that of the first contact region with respect to the reference surface.

According to Aspect 2, as compared with a configuration in which the second contact region is not provided, it is easy to maintain a state where the first member is attached to the second member.

### Aspect 3

More preferably, a width of the second contact region is smaller than a width of the first contact region.

### Aspect 4

More preferably, an inclination angle of the first contact region with respect to the reference surface is larger than an inclination angle of the second contact region with respect to the reference surface.

According to Aspect 4, as compared with a configuration in which the inclination angle of the first contact region with respect to the reference surface is smaller than the inclination angle of the second contact region with respect to the reference surface, even if a contact position is changed, it is less likely to cause detachment from a contact region, and it is easy to maintain a state where the first member is attached to the second member.

### Aspect 5

More preferably, one of the first member and the second member is a cover. The other of the first member and the second member is a holding portion. The cover includes one of a hooking portion and a hooked portion hooked to the hooking portion. The holding portion includes the other of the hooking portion and the hooked portion.

According to Aspect 5, a contact position between the hooking portion and the hooked portion can be adjusted by an inclined surface of the first contact region or the like. Therefore, an attachment state (hooked state) of the assembly (electronic device) can be easily maintained without generating rattling.

### Aspect 6

More preferably, a sandwiched portion is provided in an internal space formed between the first member and the second member. The sandwiched portion is a substrate. One of the first member and the second member is a cover that covers the substrate. The other of the first member and the second member is a holding portion that holds the substrate. The assembly is an electronic device attached to a vehicle. The cover is made of resin. The holding portion is made of metal. The holding portion is electrically connected to the substrate. The holding portion is attached to the vehicle via a bracket.

According to Aspect 6, as compared with a configuration in which the cover is made of metal, the cover can be made lightweight and inexpensive. Even if the cover 11 is made of resin, the contact position between the hooking portion and the hooked portion can be adjusted by the inclined surface of the first contact region or the like. Therefore, the attachment state (hooked state) of the assembly (electronic device) can be easily maintained without generating rattling.

### Aspect 7

More preferably, the hooking portion includes a right claw portion provided on a right side surface portion of the cover, and a left claw portion provided on a left side surface portion of the cover. When the hooking portion is hooked to the hooked portion, a rib of the cover presses one surface of the substrate, the right claw portion presses the other surface of the substrate in a z direction via a region of the holding portion in contact with the right claw portion, and the left claw portion presses the other surface of the substrate via a region of the holding portion in contact with the left claw portion.

According to Aspect 7, during hooking, a region of the hooking portion (the right claw portion, the left claw portion) in contact with the hooked portion (the right wall, the left wall) can be displaced along the inclined surface. Therefore, even if a variation in a size occurs due to a tolerance, thermal expansion, thermal contraction, or the like, fixation by hooking can be maintained without generating rattling. That is, it is easy to maintain an assembled state of an assembly such as an electronic device.

### REFERENCE SIGNS LIST

10 electronic device (assembly)
11 cover (first member)
11b1 right claw portion
11b11 first right contact region
11b12 second right contact region
11c1 left claw portion 11c11 first left contact region
11c12 second left contact region
11d1 front cut-out portion
11d2 front claw portion
11e2 rear claw portion
15 holding portion (second member)
15b1 right hooking hole
15b2 right solder connection convex portion
15c1 left hooking hole
15c2 left solder connection convex portion
15d1 front hooking convex portion
15e1 rear hooking convex portion
θ1 first inclination angle
θ2 second inclination angle

1. An assembly comprising:
a first member; and
a second member attached to the first member, wherein
a contact region where the first member and the second member are in contact with each other includes a first contact region, and
the first contact region is inclined with respect to a reference surface perpendicular to a direction in which the first member and the second member face each other.

2. The assembly according to claim 1, wherein
the contact region includes the first contact region and a second contact region,
the second contact region is adjacent to the first contact region, and is located closer to a tip end than the first contact region, and
the second contact region is parallel to the reference surface, or is inclined at an angle different from that of the first contact region with respect to the reference surface.

3. The assembly according to claim 2, wherein
a width of the second contact region is smaller than a width of the first contact region.

4. The assembly according to claim 2, wherein
an inclination angle of the first contact region with respect to the reference surface is larger than an inclination angle of the second contact region with respect to the reference surface.

5. The assembly according to claim 1, wherein
one of the first member and the second member is a cover,
the other of the first member and the second member is a holding portion,
the cover includes one of a hooking portion and a hooked portion hooked to the hooking portion, and
the holding portion includes the other of the hooking portion and the hooked portion.
